(19) United States
(12) Patent Application Publication
(10) Pub. No.: US 2024/0324213 A1
(43) Pub. Date: Sep. 26, 2024

(54) SEMICONDUCTOR MEMORY DEVICE

(71) Applicant: Kioxia Corporation, Tokyo (JP)

(72) Inventor: Takuya KONNO, Yokkaichi Mie (JP)

(21) Appl. No.: 18/595,315

(22) Filed: Mar. 4, 2024

(30) Foreign Application Priority Data
Mar. 22, 2023 (JP) 2023-045555

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A semiconductor memory device includes a stacked body including a plurality of conductive layers stacked in a first direction, a pillar structure array including a plurality of pillar structures each extending in the first direction in the stacked body and arranged in a second direction and a third direction, the plurality of pillar structures including a plurality of first pillar structures, each of which is a part of a string of memory cell transistors, a first plate-shaped structure extending in the first and second directions in the stacked body, a second plate-shaped structure extending in the first and third directions in the stacked body and disposed along an end portion of the pillar structure array in the second direction, and a support structure extending in the first direction in the stacked body and disposed where the first plate-shaped structure and the second plate-shaped structure intersect.

### CROSS-REFERENCE TO RELATED APPLICATION(S)

This application is based upon and claims the benefit of priority from Japanese Patent Application No. 2023-045555, filed Mar. 22, 2023, the entire contents of which are incorporated herein by reference.

### FIELD

Embodiments described herein relate generally to a semiconductor memory device.

### BACKGROUND

In NAND-type nonvolatile semiconductor memory devices having a three-dimensional structure in which a plurality of memory cells are stacked, it is desired to increase mechanical strength thereof.

### DESCRIPTION OF THE DRAWINGS

FIG. 1 is a planar pattern diagram schematically illustrating a configuration of a semiconductor memory device according to an embodiment.

FIGS. 2-4 are cross-sectional diagrams schematically illustrating the configuration of the semiconductor memory device according to the embodiment.

FIGS. 5-6 are cross-sectional diagrams schematically illustrating a configuration of a pillar structure of the semiconductor memory device according to the embodiment.

FIGS. 7A-7F are planar pattern diagrams schematically illustrating a part of a first manufacturing method of the semiconductor memory device according to the embodiment.

FIGS. 8A-8G are planar pattern diagrams schematically illustrating a part of a second manufacturing method of the semiconductor memory device according to the embodiment.

FIG. 9 is a planar pattern diagram schematically illustrating a configuration of a first modified example of a support structure in the semiconductor memory device according to the embodiment.

FIG. 10 is a planar pattern diagram schematically illustrating a configuration of a second modified example of the support structure in the semiconductor memory device according to the embodiment.

FIGS. 11-12 are planar pattern diagrams schematically illustrating a configuration of a semiconductor memory device according to a modified example of the embodiment.

### DETAILED DESCRIPTION

Embodiments provide a semiconductor memory device with increased mechanical strength.

In general, according to one embodiment, a semiconductor memory device includes: a stacked body including a plurality of conductive layers stacked in a first direction; a pillar structure array including a plurality of pillar structures each extending in the first direction in the stacked body, the plurality of pillar structures being arranged in a second direction intersecting the first direction and a third direction intersecting the first and second directions, the plurality of pillar structures including a plurality of first pillar structures, each of which is a part of a string of memory cell transistors; a first plate-shaped structure extending in the first and second directions in the stacked body, the first plate-shaped structure partitioning the pillar structure array in the third direction; a second plate-shaped structure extending in the first and third directions in the stacked body, the second plate-shaped structure being disposed along an end portion of the pillar structure array in the second direction; and a support structure extending in the first direction in the stacked body and disposed where the first plate-shaped structure and the second plate-shaped structure intersect.

Hereinafter, certain embodiments will be described with reference to drawings.

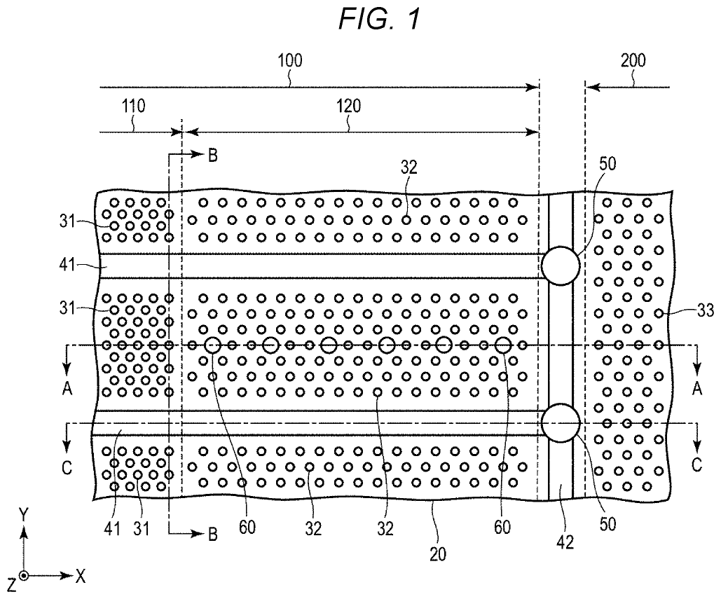

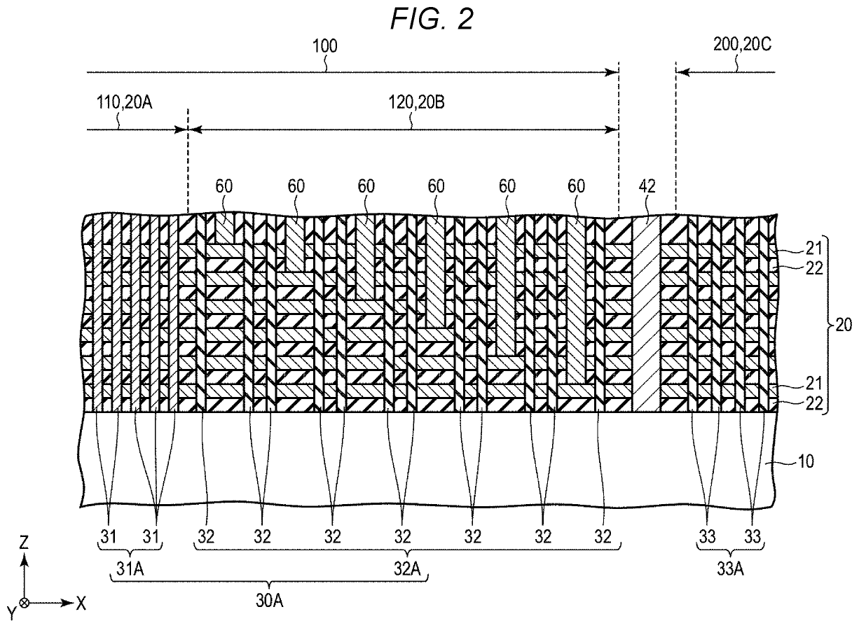

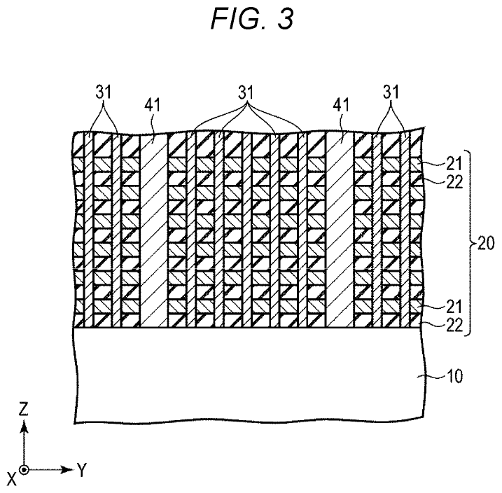

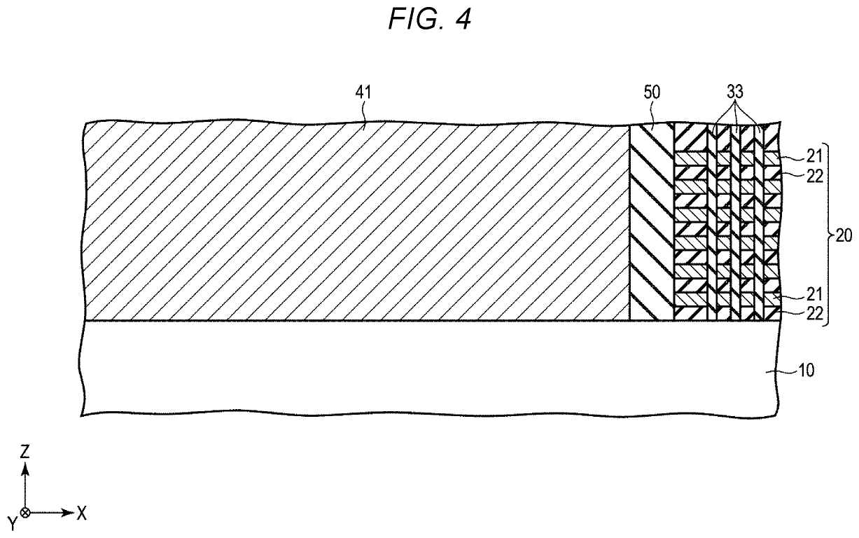

FIG. 1 is a planar pattern diagram schematically illustrating a configuration of a NAND type nonvolatile semiconductor memory device having a three-dimensional structure according to an embodiment. FIGS. 2 to 4 are cross-sectional diagrams schematically illustrating the configuration of the nonvolatile semiconductor memory device illustrated in FIG. 1. The cross section taken along the line A-A of FIG. 1 corresponds to FIG. 2, the cross section taken along the line B-B of FIG. 1 corresponds to FIG. 3, and the cross section taken along the line C-C of FIG. 1 corresponds to FIG. 4.

The X direction, the Y direction, and the Z direction illustrated in FIG. 1 and the like are directions that intersect with one another. Specifically, the X direction, the Y direction, and the Z direction are orthogonal to one another.

The semiconductor memory device according to the present embodiment includes a main region 100 and a dummy region 200, and the main region 100 and the dummy region 200 are disposed on the same semiconductor substrate. The main region 100 includes a memory region 110 and a contact region 120 adjacent to each other in the X direction.

In the main region 100 and the dummy region 200, a structure including a stacked body 20, a plurality of pillar structures 31, a plurality of pillar structures 32, a plurality of pillar structures 33, a plurality of plate-shaped structures 41, plate-shaped structures 42, a plurality of support structures 50, and a plurality of contacts 60, is disposed on a lower region 10 including the semiconductor substrate.

The stacked body 20 includes a stacked portion 20A disposed in the memory region 110, a stacked portion 20B disposed in the contact region 120, and a stacked portion 20C disposed in the dummy region 200.

Moreover, the stacked body 20 includes a plurality of conductive layers 21 stacked to be separated from one another in Z direction. More specifically, the stacked body 20 includes the plurality of conductive layers 21 and a plurality of insulation layers 22 that are stacked alternately in the Z direction.

Each conductive layer 21 functions as a word line or a select gate line with respect to a NAND string. The NAND string has a structure in which one or more lower select transistors, one or more upper select transistors, and a plurality of memory cells disposed between the one or more lower select transistors and the one or more upper select transistors are stacked in the Z direction. Each insulation layer 22 has a function of insulating between adjacent conductive layers 21. The conductive layer 21 is formed with a metallic material, such as tungsten, and the insulation layer 22 is formed with an insulating material, such as a silicon oxide. One or more of the conductive layers 21 including the bottom one function as a lower select gate line, and one or more of the conductive layers 21 including the top one function as an upper select gate line. Moreover, the plurality of conductive layers 21 that are between the one or more conductive layers 21 including the bottom one and the one or more conductive layers 21 including the top one function as word lines.

The plurality of pillar structures 31 and the plurality of pillar structures 32 are disposed in the main region 100, and the plurality of pillar structures 33 are disposed in the dummy region 200. Each pillar structure 31, each pillar structure 32, and each pillar structure 33 extend in the Z direction in the stacked body 20.

The plurality of pillar structures 31 are disposed in the memory region 110 and extend in the Z direction in the stacked portion 20A. Each pillar structure 31 is used for the NAND string. Namely, the NAND string is formed with the pillar structure 31 and the plurality of conductive layers 21 surrounding the pillar structure 31. More specifically, the NAND string including one or more upper select transistors, memory cells, and one or more lower select transistors is formed with the pillar structure 31 and respective conductive layers 21 serving as the upper select gate line, word lines, and the lower select gate line.

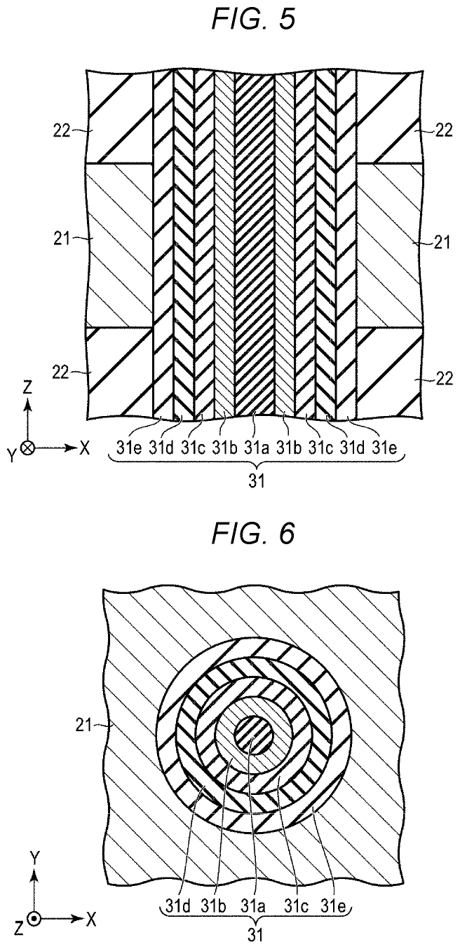

FIGS. 5 and 6 are cross-sectional diagrams each schematically illustrating the configuration of the pillar structure 31. FIG. 5 is a cross-sectional diagram parallel to the Z direction, and FIG. 6 is a cross-sectional diagram perpendicular to the Z direction.

As illustrated in FIGS. 5 and 6, the pillar structure 31 includes a core insulation layer 31a, a semiconductor layer 31b surrounding a side surface of the core insulation layer 31a, a tunnel insulation layer 31c surrounding a side surface of the semiconductor layer 31b, a charge accumulation layer 31d surrounding a side surface of the tunnel insulation layer 31c, and a block insulating layer 31e surrounding a side surface of the charge accumulation layer 31d.

The plurality of pillar structures 32 are disposed in the contact region 120 and extend in the Z direction in the stacked portion 20B. Each pillar structure 32 is not used for the NAND string. The plurality of pillar structures 32 have a function of supporting the plurality of insulation layers 22 during a replacement process described below. Each pillar structure 32 has a structure different from each pillar structure 31 and is formed with a material different from the material of each pillar structure 31.

The plurality of pillar structures 33 are disposed in the dummy region 200 and extend in the Z direction in the stacked portion 20C. Each pillar structure 33 is not used for the NAND string and has a structure different from each pillar structure 31. Each pillar structure 33 has the same structure as each pillar structure 32 and is formed with the same material as the material of each pillar structure 32.

The plurality of pillar structures 31 and the plurality of pillar structures 32 provided in the main region 100 are arranged in the X direction and the Y direction, and a pillar structure array 30A (shown in FIG. 2) includes the plurality of pillar structures 31 and the plurality of pillar structures 32 provided in the main region 100.

Accordingly, the plurality of pillar structures 31 provided in the memory region 110 are also arranged in the X direction and the Y direction, and a pillar structure array 31A includes the plurality of pillar structures 31 provided in the memory region 110.

Similarly, the plurality of pillar structures 32 provided in the contact region 120 are also arranged in the X direction and the Y direction, and a pillar structure array 32A includes the plurality of pillar structures 32 provided in the contact region 120.

Moreover, the plurality of pillar structures 33 provided in the dummy region 200 are also arranged in the X direction and the Y direction, and a pillar structure array 33A includes the plurality of pillar structures 33 provided in the dummy region 200.

A plurality of plate-shaped structures 41 are arranged in the Y direction, and each of the plate-shaped structures 41 extends in the X direction and the Z direction in the stacked body 20.

Each of the plate-shaped structures 41 partitions (divides) the main region 100 in the Y direction, and the main region 100 is partitioned (divided) into a plurality of sub regions in the Y direction by the plurality of plate-shaped structures 41. Namely, each of the plate-shaped structures 41 partitions (divides) the pillar structure array 30A in the Y direction, and the pillar structure array 30A is partitioned (divided) by the plurality of plate-shaped structures 41 in the Y direction into the plurality of sub arrays.

Accordingly, each of the plate-shaped structures 41 partitions (divides) also the memory region 110 in the Y direction, and the memory region 110 is partitioned (divided) into a plurality of sub regions in the Y direction by the plurality of plate-shaped structures 41. Namely, each of the plate-shaped structures 41 partitions (divides) the pillar structure array 31A in the Y direction, and the pillar structure array 31A is partitioned (divided) by the plurality of plate-shaped structures 41 in the Y direction into the plurality of sub arrays.

Similarly, each of the plate-shaped structures 41 partitions (divides) also the contact region 120 in the Y direction, and the contact region 120 is partitioned (divided) into a plurality of sub regions in the Y direction by the plurality of plate-shaped structures 41. Namely, each of the plate-shaped structures 41 partitions (divides) the pillar structure array 32A in the Y direction, and the pillar structure array 32A is partitioned (divided) by the plurality of plate-shaped structures 41 in the Y direction into the plurality of sub arrays.

The plate-shaped structure 42 extends in the Y direction and the Z direction in the stacked body 20. The plate-shaped structure 42 is disposed along an end in the X direction of the pillar structure array 30A, and is disposed between the pillar structure array 32A and the pillar structure array 33A. The pillar structure array 32A is disposed between the pillar structure array 31A and the plate-shaped structure 42.

The plurality of support structures 50 are arranged in the Y direction. Each support structure 50 is disposed corresponding to a position of intersection of a first plane which extends in the X and Z directions and which includes an inside of the plate-shaped structure 41 and a second plane which extends in the Y and Z directions and which includes an inside of the plate-shaped structure 42, extending in the Z direction in the stacked body 20. Accordingly, each support structure 50 is in contact with the stacked body 20, the plate-shaped structure 41, and the plate-shaped structure 42. Each support structure 50 has a pillar shape extending in the Z direction, and each support structure 50 has a circular pattern when observed from the Z direction.

The plurality of support structures 50 have a function of supporting the plurality of insulation layers 22 during a replacement process described below. In particular, each support structure 50 has a function of effectively supporting the plurality of insulation layers 22 at a corner portion of a region partitioned by the plate-shaped structure 41 and the plate-shaped structure 42 during the replacement process.

The plurality of contacts 60 are respectively connected to the plurality of conductive layers 21 in the stacked portion 20B. Specifically, as FIG. 2 illustrated, each contact 60 is connected to the corresponding conductive layer 21. Each contact 60 except for the contact 60 connected to the top conductive layer 21 is electrically connected to its corresponding conductive layer 21, and is electrically insulated from and extends in the Z direction through one or more other conductive layers 21 located on an upper layer side of its corresponding conductive layer 21.

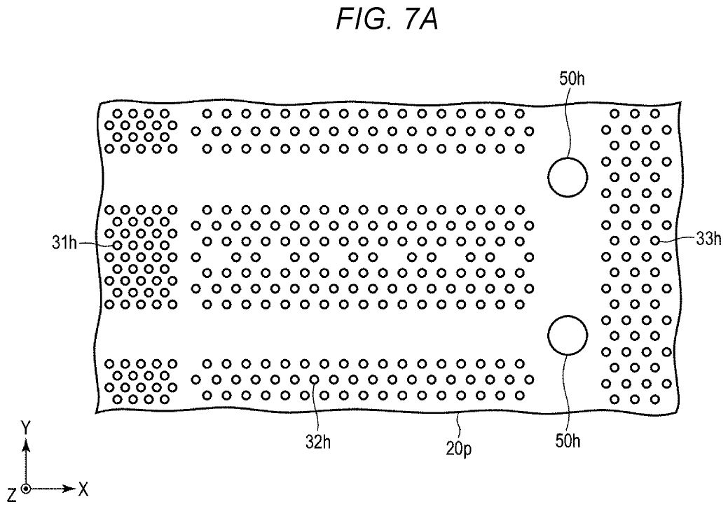

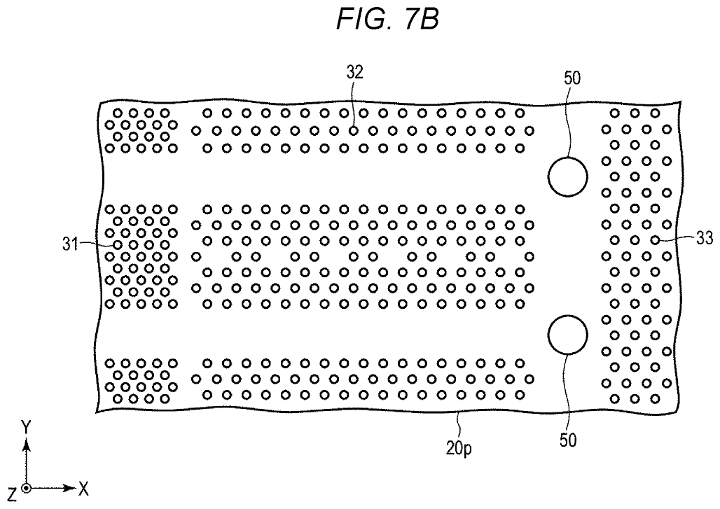

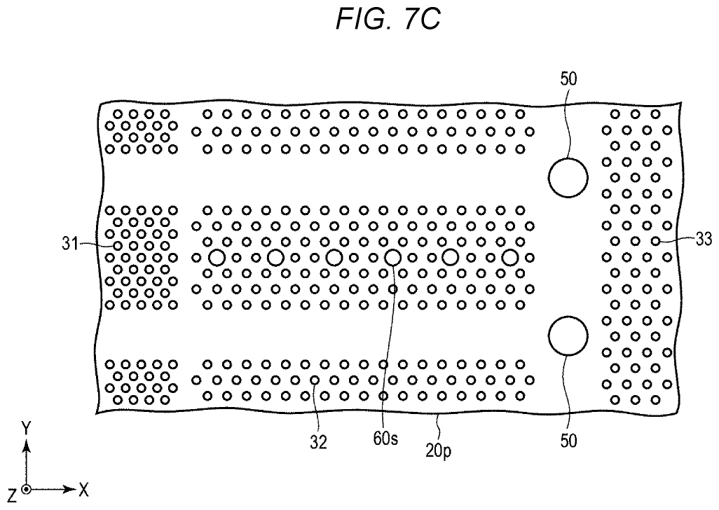

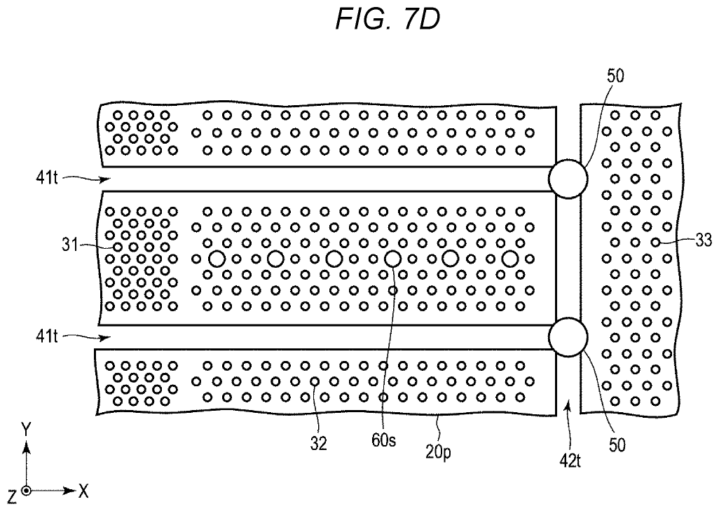

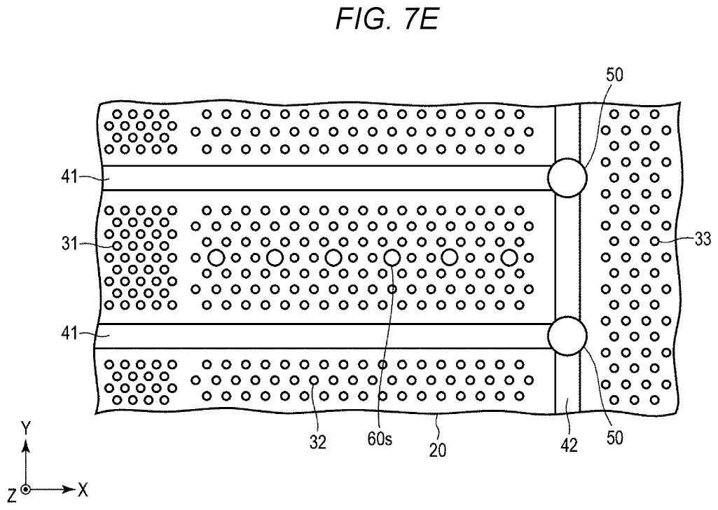

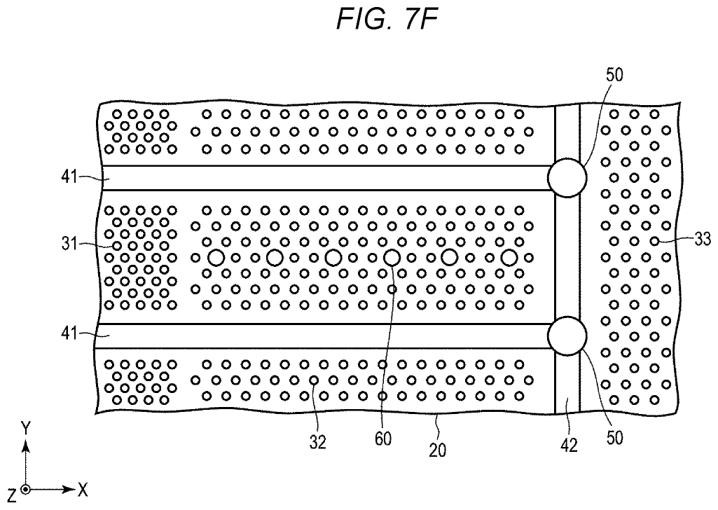

FIGS. 7A to 7F are planar pattern diagrams schematically illustrating a first manufacturing method of the semiconductor memory device according to the present embodiment.

First, a structure illustrated in FIG. 7A is formed. Specifically, a preliminary stacked body 20p for forming the stacked body 20 is formed. The preliminary stacked body 20p has a structure in which the insulation layers 22 and sacrificial layers to be replaced by the conductive layers 21 are alternately stacked. Subsequently, holes 31h for the pillar structures 31, holes 32h for the pillar structures 32, holes 33h for the pillar structures 33, and holes 50h for the support structures 50 are formed in the preliminary stacked body 20p, during the same process.

Next, a structure illustrated in FIG. 7B is formed. Specifically, the pillar structure 31 as illustrated in FIGS. 5 and 6 is formed in each hole 31h. The holes 32h, 33h, and 50h are filled up with an insulating material such as a silicon oxide layer during the same process to respectively form the pillar structure 32, the pillar structure 33, and the support structure 50.

Next, a structure illustrated in FIG. 7C is formed. Specifically, a plurality of holes for the contacts 60 are formed in the preliminary stacked body 20p, and sacrificial layers 60s, such as an amorphous silicon layer, are formed in the plurality of holes.

Next, a structure illustrated in FIG. 7D is formed. Specifically, grooves 41t for the plate-shaped structures 41 and a groove 42t for the plate-shaped structure 42 are formed in the preliminary stacked body 20p.

Next, a structure illustrated in FIG. 7E is formed. Specifically, the replacement process is performed as follows. First, the sacrificial layers in the preliminary stacked body 20p is etched through the grooves 41t and 42t to form a plurality of spaces between the plurality of insulation layers 22 in the preliminary stacked body 20p. At this time, the grooves 41t and 42t are formed in the preliminary stacked body 20p, and the plurality of spaces are respectively formed between the plurality of insulation layers 22 in the preliminary stacked body 20p. Accordingly, the strength of the preliminary stacked body 20p is weakened. In the present embodiment, since the support structures 50 are formed in advance, it is possible to increase the strength of the preliminary stacked body 20p.

Subsequently, the plurality of spaces are filled up with a conductive material, such as tungsten, to form the plurality of conductive layers 21. Consequently, the stacked body 20 is formed in which the plurality of conductive layers 21 and the plurality of insulation layers 22 are alternately stacked. Moreover, the grooves 41t and 42t are also filled up with the conductive material, such as tungsten, to respectively form the plate-shaped structures 41 and 42.

Next, a structure illustrated in FIG. 7F is formed. Specifically, the contacts 60 are formed by respectively replacing the sacrificial layers 60s by a conductive material, such as tungsten.

In the manner described above, the semiconductor memory device having the structure as illustrated in FIGS. 1 to 4 is obtained. As can be seen from the above description, in this manufacturing method, the support structure 50 is formed with the same material as the material of the pillar structures 32 and 33.

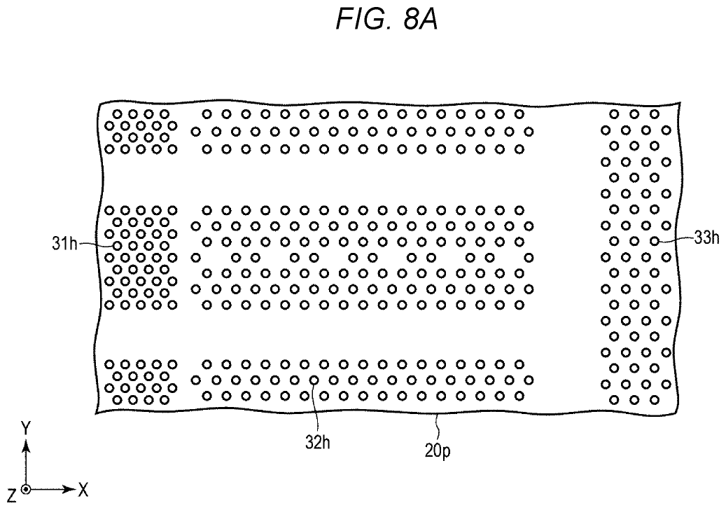

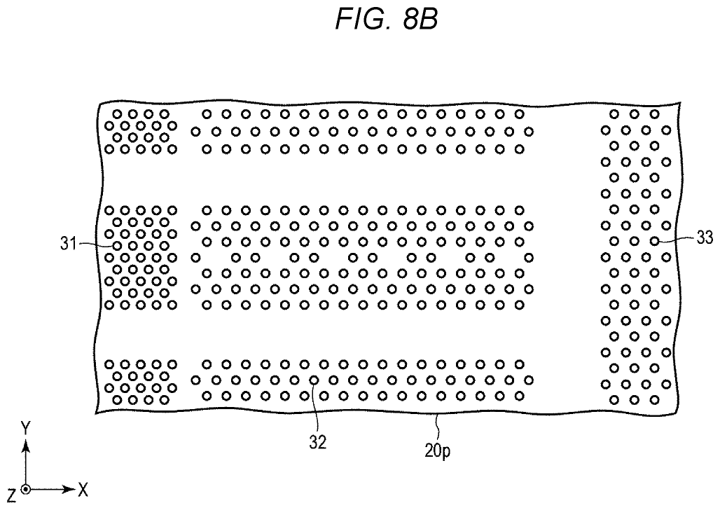

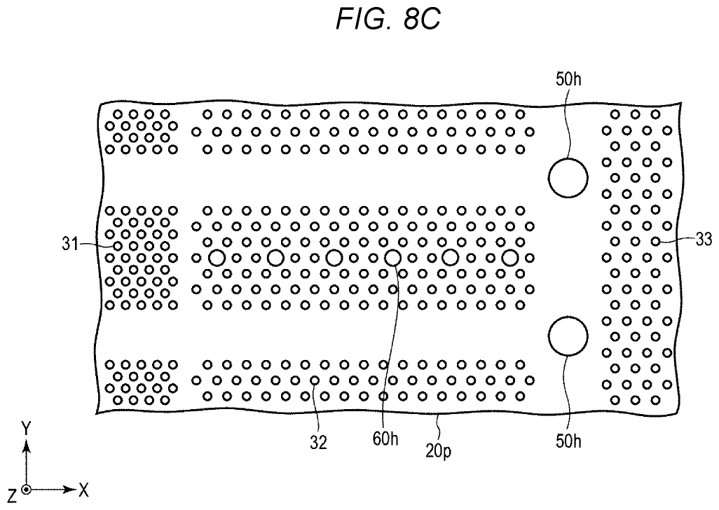

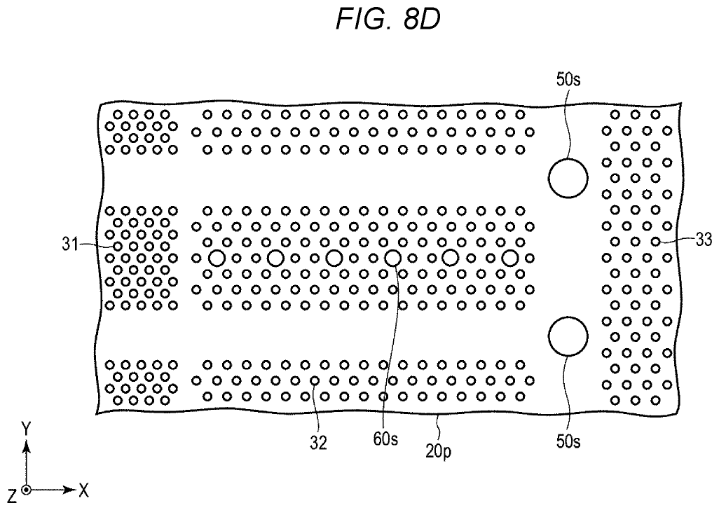

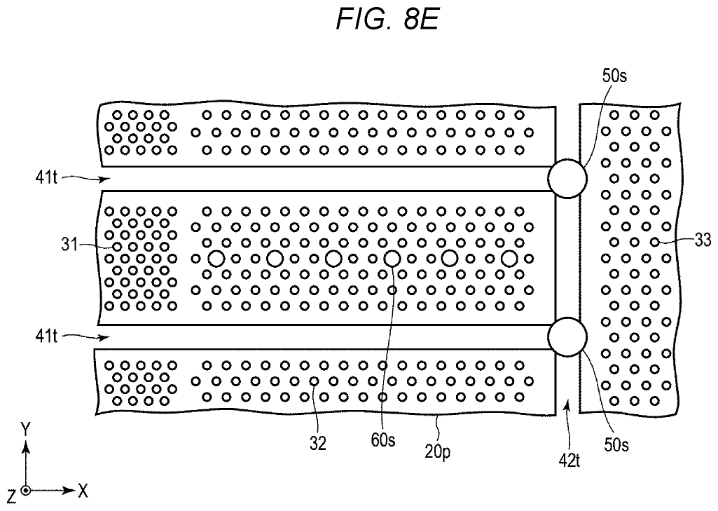

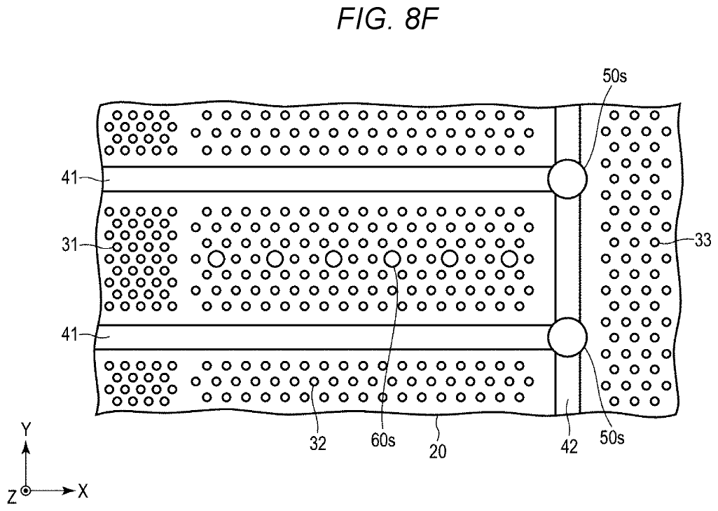

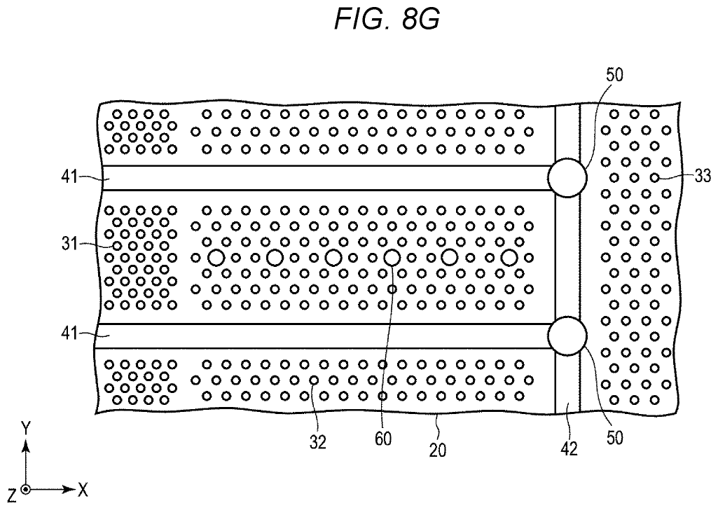

FIGS. 8A to 8G are planar pattern diagrams schematically illustrating a second manufacturing method of the semiconductor memory device according to the present embodiment.

First, a structure illustrated in FIG. 8A is formed. Specifically, similar to the first manufacturing method, the preliminary stacked body 20p in which the insulation layers 22 and sacrificial layers are alternately stacked is formed. Subsequently, the holes 31h for the pillar structures 31, the holes 32h for the pillar structures 32, and the holes 33h for the pillar structures 33 are formed in the preliminary stacked body 20p.

Next, a structure illustrated in FIG. 8B is formed. Specifically, the pillar structure 31 as illustrated in FIGS. 5 and 6 is formed in each hole 31h. The holes 32h and 33h are filled up with an insulating material such as a silicon oxide layer during the same process to respectively form the pillar structures 32 and 33.

Next, a structure illustrated in FIG. 8C is formed. Specifically, the holes 50h for the support structures 50 and holes 60h for the contacts 60 are formed in the preliminary stacked body 20p during the same process.

Next, a structure illustrated in FIG. 8D is formed. Specifically, the holes 50h and the holes 60h are filled up with a sacrificial material, such as amorphous silicon, to respectively form sacrificial layers 50s for the support structures 50 and the sacrificial layers 60s for the contacts 60 during the same process.

Next, a structure illustrated in FIG. 8E is formed. Specifically, the grooves 41t for the plate-shaped structures 41 and the groove 42t for the plate-shaped structure 42 are formed in the preliminary stacked body 20p.

Next, a structure illustrated in FIG. 8F is formed. Specifically, by performing the replacement process similar to the first manufacturing method, the stacked body 20 is formed, and the plate-shaped structures 41 and 42 are further formed. In the present manufacturing method, the sacrificial layers 50s for the support structures 50 are formed in advance when performing the replacement process. Accordingly, it is possible to increase the strength of the preliminary stacked body 20p when performing the replacement process, similar to the first manufacturing method.

Next, a structure illustrated in FIG. 8G is formed. Specifically, the support structures 50 and the contacts 60 are respectively formed by replacing the sacrificial layers 50s and the sacrificial layers 60s by a conductive material, such as tungsten, during the same process.

In the manner described above, the semiconductor memory device having the structure as illustrated in FIGS. 1 to 4 is obtained. As can be seen from the above description, in this manufacturing method, the support structure 50 is formed with the same material as the material of the contact 60.

It is to be noted that in the process illustrated in FIG. 8G in the second manufacturing method described above, the support structure 50 may be formed using the sacrificial layers 50s, instead of replacing the sacrificial layers 50s by the conductive material such as tungsten.

As described above, in the present embodiment, it is possible to increase the strength of the preliminary stacked body 20p since the support structures 50 or the sacrificial layers 50s for the support structures 50 are formed in advance when performing the replacement process. Accordingly, in the present embodiment, it is possible to obtain the semiconductor memory device having the increased mechanical strength.

Moreover, in the present embodiment, the support structures 50 can be formed during the same process as other components (e.g., the pillar structures 32 and 33 or the contacts 60), and thereby it is possible to reduce an increase in manufacturing processes associated with the formation of the support structures 50.

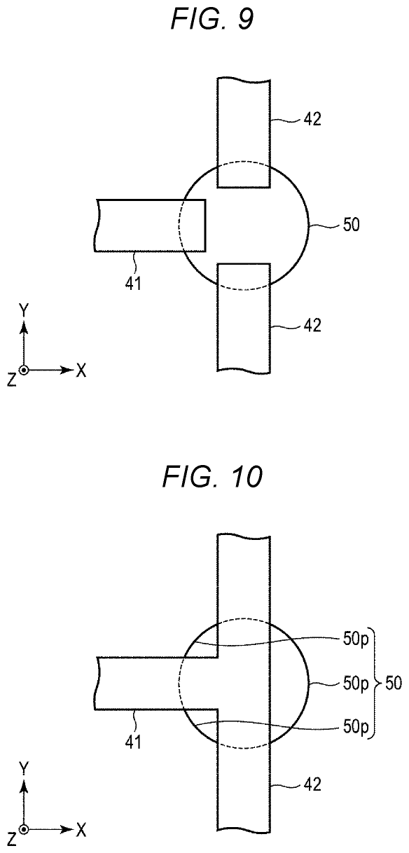

FIG. 9 is a planar pattern diagram schematically illustrating a configuration of a first modified example of the support structure 50 in the semiconductor memory device according to the present embodiment.

The support structure 50 has a circular pattern when observed from the Z direction in the above-described embodiment, but in the first modified example, the support structure 50 has a pattern in which one or more portions of the circular pattern are not present when observed from the Z direction. Specifically, one or more portions of the circular pattern are not present due to at least one of the plate-shaped structures 41 and 42 (in the example illustrated in FIG. 9, both plate-shaped structures 41 and 42).

Even using the support structure 50 having the shape as the first modified example, it is possible to obtain the same advantageous effects as the above-described embodiment.

FIG. 10 is a planar pattern diagram schematically illustrating a configuration of a second modified example of the support structure 50 in the semiconductor memory device according to the present embodiment.

The support structure 50 is divided into a plurality of sub portions 50p, each having a pillar shape, in the second modified example. Specifically, the support structure 50 is divided into the plurality of sub portions 50p due to at least one of the plate-shaped structures 41 and 42 (in the example illustrated in FIG. 10, both plate-shaped structures 41 and 42). More specifically, the support structure 50 has a shape in which the circular pattern is divided into a plurality of sub patterns when observed from the Z direction.

Even using the support structure 50 having the shape as the second modified example, it is possible to obtain the same advantageous effects as the above-described embodiment.

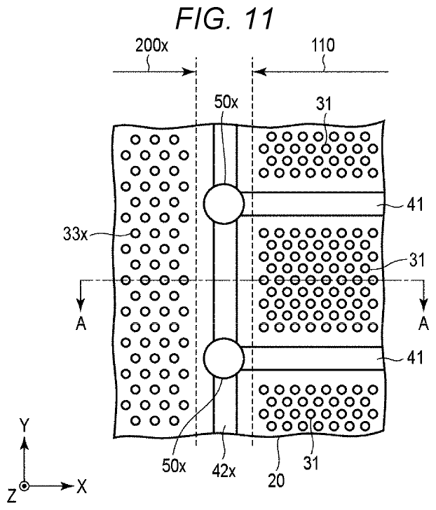

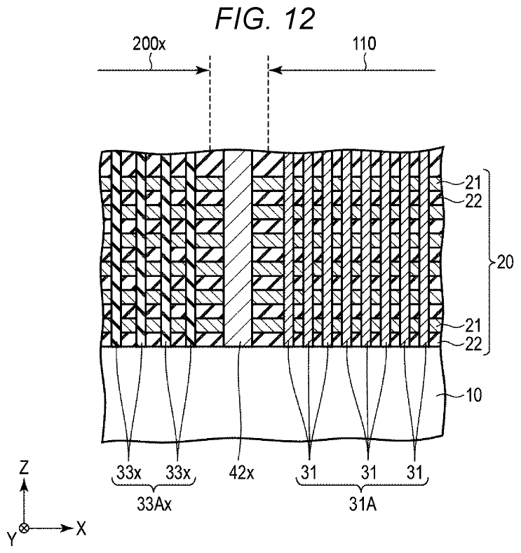

FIG. 11 is a planar pattern diagram schematically illustrating a configuration of a semiconductor memory device according to a modified example of the present embodiment. FIG. 12 is a cross-sectional diagram schematically illustrating the configuration of the semiconductor memory device illustrated in FIG. 11. A cross section taken along the line A-A of FIG. 11 corresponds to FIG. 12.

The above-described embodiment mainly described the configuration on one end side in the X direction of the memory region 110 (i.e., the configuration on the contact region 120 side of the memory region 110). In contrast, the present modified example relates to a configuration on the other end side in the X direction of the memory region 110 (a configuration on the side opposite to the contact region 120 of the memory region 110).

As illustrated in FIGS. 11 and 12, a dummy region 200x in which a plurality of pillar structures 33x are disposed is disposed on the other end side of the memory region 110, and a plate-shaped structure 42x is disposed between the pillar structure array 31A and a pillar structure array 33Ax. Similar to the above-described embodiment, each support structure 50x is disposed corresponding to a position of intersection of a first plane which extends on the X and Z directions and which includes an inside of the plate-shaped structure 41 and a second plane which extends in the Y and Z directions and which includes an inside of the plate-shaped structure 42x, extending in the Z direction in the stacked body 20. The basic configuration of the dummy region 200x, the pillar structure 33x, the pillar structure array 33Ax, the plate-shaped structure 42x and the support structures 50x in the present modified example is similar to the configuration of the dummy region 200, the pillar structures 33, the pillar structure array 33A, the plate-shaped structure 42, and the support structure 50 in the above-described embodiment.

The contact region 120 including the pillar structure array 32A and the dummy region 200 including the pillar structure array 33A may be disposed on one end side of the memory region 110 similarly to the above-described embodiment, but it is not necessarily limited to the configuration of the above-described embodiment. For example, the stacked body 20 in the contact region 120 may have an end processed into a stepped shape in the X direction. In this case, the plurality of contacts 60 are connected to the plurality of conductive layers 21 located in the stepped-shape end. Moreover, in this case, the dummy region 200 including the pillar structure array 33A may not need to be disposed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a plurality of conductive layers stacked in a first direction;
a pillar structure array including a plurality of pillar structures each extending in the first direction in the stacked body, the plurality of pillar structures being arranged in a second direction intersecting the first direction and a third direction intersecting the first and second directions, the plurality of pillar structures including a plurality of first pillar structures, each of which is a part of a string of memory cell transistors;
a first plate-shaped structure extending in the first and second directions in the stacked body, the first plate-shaped structure partitioning the pillar structure array in the third direction;
a second plate-shaped structure extending in the first and third directions in the stacked body, the second plate-shaped structure being disposed along an end portion of the pillar structure array in the second direction; and
a support structure extending in the first direction in the stacked body and disposed where the first plate-shaped structure and the second plate-shaped structure intersect.

2. The semiconductor memory device according to claim 1, wherein
the pillar structure array includes a first pillar structure array including the plurality of first pillar structures and a second pillar structure array disposed between the first pillar structure array and the second plate-shaped structure, the second pillar structure array including a plurality of second pillar structures, each of is not a part of a string of memory cell transistors.

3. The semiconductor memory device according to claim 2, wherein
each of the second pillar structures has a structure different from each of the first pillar structures.

4. The semiconductor memory device according to claim 2, wherein
the support structure is formed with the same material as a material of the plurality of second pillar structures.

5. The semiconductor memory device according to claim 2, wherein
the stacked body includes a first stacked portion and a second stacked portion adjacent to the first stacked portion in the second direction,
the plurality of first pillar structures extend in the first direction in the first stacked portion, and
the plurality of second pillar structures extend in the first direction in the second stacked portion.

6. The semiconductor memory device according to claim 5, further comprising
a plurality of contacts respectively connected to the plurality of conductive layers in the second stacked portion.

7. The semiconductor memory device according to claim 6, wherein
a first contact of the plurality of contacts is connected to a first conductive layer of the plurality of conductive layers, and the first contact extends in the first direction through one or more conductive layers that are located on an upper layer side of the first conductive layer.

8. The semiconductor memory device according to claim 6, wherein
the support structure is formed with the same material as a material of the plurality of contacts.

9. The semiconductor memory device according to claim 6, further comprising
a dummy pillar structure array including a plurality of dummy pillar structures, each of which extends in the first direction in the stacked body and is not a part of a string of memory cell transistors, wherein
the second plate-shaped structure is disposed between the second pillar structure array and the dummy pillar structure array.

10. The semiconductor memory device according to claim 9, wherein
the stacked body further includes a third stacked portion adjacent to the second stacked portion in the second direction, and
each of the dummy pillar structures extends in the first direction in the third stacked portion.

11. The semiconductor memory device according to claim 1, further comprising
a dummy pillar structure array including a plurality of dummy pillar structures each of which extends in the first direction in the stacked body and is not a part of a string of memory cell transistors, wherein
the second plate-shaped structure is disposed between the first pillar structure array and the dummy pillar structure array.

12. The semiconductor memory device according to claim 1, wherein
the support structure is in contact with the stacked body, the first plate-shaped structure, and the second plate-shaped structure.

13. The semiconductor memory device according to claim 1, wherein
the support structure has a pillar shape.

14. The semiconductor memory device according to claim 13, wherein
the support structure has a circular pattern when observed from the first direction.

15. The semiconductor memory device according to claim 13, wherein
the support structure has a pattern in which one or more portions of the circular pattern are not present when observed from the first direction.

16. The semiconductor memory device according to claim 1, wherein
the support structure is divided into a plurality of portions, each having a pillar shape.

17. The semiconductor memory device according to claim 1, wherein
the stacked body includes the plurality of conductive layers and a plurality of insulation layers alternately stacked in the first direction.

18. A semiconductor memory device comprising:
first and second stacked bodies, each including a plurality of conductive layers and a plurality of insulating layers alternately stacked in a first direction;
a plurality of memory pillars each including a semiconductor layer and extending in the first direction in the first stacked body, the plurality of memory pillars arranged in a second direction intersecting the first direction and a third direction intersecting the first and second directions;
a plurality insulating pillars each extending in the first direction in the second stacked body, the plurality of insulating pillars arranged in the second direction and the third direction;
a first plate-shaped structure extending in the first and second directions in the first and second stacked bodies to partition the first and second stacked bodies in the third direction;
a second plate-shaped structure extending in the first and third directions at an end portion of the second stacked body in the second direction away from the first stacked body; and
a support structure extending in the first direction in the second stacked body and disposed where the first plate-shaped structure and the second plate-shaped structure intersect.

19. The semiconductor memory device according to claim 18, wherein the support structure is a cylindrical column and a diameter of the cylindrical column is greater than a thickness of the first plate-shaped structure in the third direction and is greater than a thickness of the second plate-shaped structure in the second direction.

20. The semiconductor memory device according to claim 18, further comprising:
a third stacked body adjacent to the end portion of the second stacked body in the second direction and including a plurality of conductive layers and a plurality of insulating layers alternately stacked in the first direction; and
a plurality dummy pillars each extending in the first direction in the third stacked body, the plurality of dummy pillars arranged in the second direction and the third direction and formed with the same material as the insulating pillars.
